(19) United States
(12) Patent Application Publication
(10) Pub. No.: US 2013/0242656 A1
(43) Pub. Date: Sep. 19, 2013

(54) HOST EQUIPMENT, MEMORY CONTROLER, AND MEMORY DEVICE

(71) Applicants: Kenji SAKAUE, Kanagawa-ken (JP); Taro IWASHIRO, Kanagawa-ken (JP)

(72) Inventors: Kenji SAKAUE, Kanagawa-ken (JP); Taro IWASHIRO, Kanagawa-ken (JP)

(73) Assignee: KABUSHIKI KAISHA TOSHIBA, Tokyo (JP)

(21) Appl. No.: 13/601,324

(22) Filed: Aug. 31, 2012

(30) Foreign Application Priority Data
Mar. 15, 2012 (JP) 2012-058724

(51) Int. Cl. G11C 16/06

(52) U.S. Cl. 365/185.09

(57) ABSTRACT

A memory controller includes a processor that includes a monitoring module, a control module, and a parity generating module. The monitoring module receives a data sequence and checks the data sequence for a designated pattern. The control module determines page size of data sequences that include the designated pattern and arranges an idle area for each page based on the total data quantity and the size of the data sequence, where the data quantity of the data stored in each page is uniform. The parity generating module generates the extended parity in the idle area based on a portion of the data stored in each page and the management information of the page. In each page, the control module stores a portion of the data and the extended parity in the idle area.

### CROSS-REFERENCE TO RELATED APPLICATION

This application is based upon and claims the benefit of priority from Japanese Patent Application No. 2012-058724, filed Mar. 15, 2012; the entire contents of which are incorporated herein by reference.

### FIELD

Embodiments described herein relate to an ECC (error correction code) circuit, and a compression technology.

### BACKGROUND

When data are read from a memory card (NAND type flash memory), if the data is not correctly read, a bit error occurs. In order to correct the bit error, an ECC circuit for carrying out error correction is arranged in the memory card. The ECC circuit generates a parity bit on the basis of the user data when it was written (write data).

Also, in the memory cell array, in addition to the user area where the user data are stored, a management data region is arranged that stores the parity bit generated on the basis of the user data.

### DESCRIPTION OF THE DRAWINGS

FIG. 1 is a schematic diagram illustrating a memory card according to an embodiment.

FIG. 2 is a schematic diagram illustrating the signals allotted to the pins of the memory card.

FIG. 3 is a diagram illustrating an example of the configuration of the memory card.

FIG. 4 is a schematic diagram illustrating a memory cell array in the memory card.

FIG. 5 is a diagram illustrating the distribution of the threshold of a memory cell transistor according to an embodiment.

FIG. 6 is a diagram illustrating an example of the format of the data sent from a host equipment according to an embodiment.

FIG. 7A and FIG. 7B are schematic diagrams illustrating the sequence of the generation of parity according to an embodiment.

FIG. 8 is a flow chart illustrating the method for generating the parity according to an embodiment.

FIG. 9 is another schematic diagram illustrating the memory cell array.

FIG. 10 is a schematic diagram illustrating the memory cell array as modified according to a first example.

FIG. 11 is a schematic diagram illustrating the memory cell array as modified according to a second example.

FIG. 12 is a diagram illustrating a micro-processing unit (MPU) according to an embodiment.

FIG. 13 is a schematic diagram illustrating a data sequence generated according to an embodiment.

FIG. 14 is a schematic diagram illustrating a compression method of the data sequence.

FIG. 15 is another schematic diagram illustrating the compression method of the data sequence.

FIG. 16 is a diagram illustrating an encoder according to an embodiment.

FIG. 17A and FIG. 17B are schematic diagrams illustrating a data sequence of the generation of parity generated according to an embodiment.

FIG. 18 is another diagram illustrating an MPU related to Embodiment 2.

FIG. 19A and FIG. 19B are schematic diagrams illustrating a compression method of the data sequence of FIG. 17A and FIG. 17B.

FIG. 20 is another schematic diagram illustrating the compression method of the data sequence.

FIG. 21 is another schematic diagram illustrating the compression method of the data sequence.

FIG. 22 is a schematic diagram illustrating a memory system according to an embodiment.

FIG. 23 is a diagram illustrating components of an MPU of the memory system.

FIG. 24A, FIG. 24B, and FIG. 24C are schematic diagrams illustrating compressed data and parity data generated on the basis of the compressed data that are stored in the memory system.

### DETAILED DESCRIPTION

In general, embodiments will be explained with reference to figures. The same reference numbers are used throughout all of the figures. However, the figures are merely schematic diagrams, and it should be understood that the relationship between thickness and the planar dimensions and the ratio of the thicknesses of the various layers are not shown to scale. Consequently, any specific thickness and dimensions should be ascertained with reference to the following explanation. Also, the figures contain portions with different dimensional relationships and ratios.

According to one embodiment, there is provided a technology that improves error correction and provides a compression technology in a memory device.

According to the memory controller of the present embodiment, it has a processor that has the following parts or modules: a monitoring part that receives the write data and checks whether the data sequence of a designated pattern over a designated data length is contained in the write data, and a control part, which works as follows: when it is determined that the data sequence with the designated pattern is contained, the size of the page (the unit for the en bloc write of the data in the memory cell array) having memory cells that can hold the data and arranged in a matrix configuration is determined. Corresponding to the total data quantity and the size of the data, an idle area for each page is arranged, and is configured so that the data quantity of the write data stored in each page is even; the memory controller also has a parity generating part that generates the extended parity in the idle area and on the basis of a portion of the write data stored in each page and the management information of the page; and the control part stores the extended parity in the idle area while a portion of the write data are stored in each page.

According to the host equipment related to the embodiment, there is a control part that works as follows: the size of the page that is the unit for the en bloc write of data is determined. When it is determined that there is a designated or larger idle area on the last page of the en bloc write corresponding to the total write data quantity and the size of the write data, a data group including the logic address, the data, and the data sequence of the designated pattern succeeding the data and corresponding to the idle area is generated. When there is no designated or larger idle area on the last page, the data group including the logic address and the data is generated. Also, there is a data output part that outputs the write data and the data sequence generated by the control part.

Also, according to the memory device related to the embodiment, there are the following parts: a storage part that can hold the data on each page acting as the unit for the en bloc write of data, a control part that inserts the invalid data sequence at multiple sites of the first data sequence corresponding the capacity information of the written first data sequence and the size of the page of the storage part, and a parity generating part, which generates the third data sequence composed of the second data sequence as the unit for partitioning the invalid data sequence and the management information in the data; and the control part inserts the extended parity into the invalid data sequence.

### Embodiment 1

According to the present embodiment, when the user data (write data) stored in each page are read, it is possible to improve error correction in read operations by using the user data and extended parity for each page. In the following, the configuration related to Embodiment 1 will be explained. In this embodiment, the extended parity in write and the normal parity (that is normally generated) are generated.

### (1. About the Overall Configuration of the Memory System)

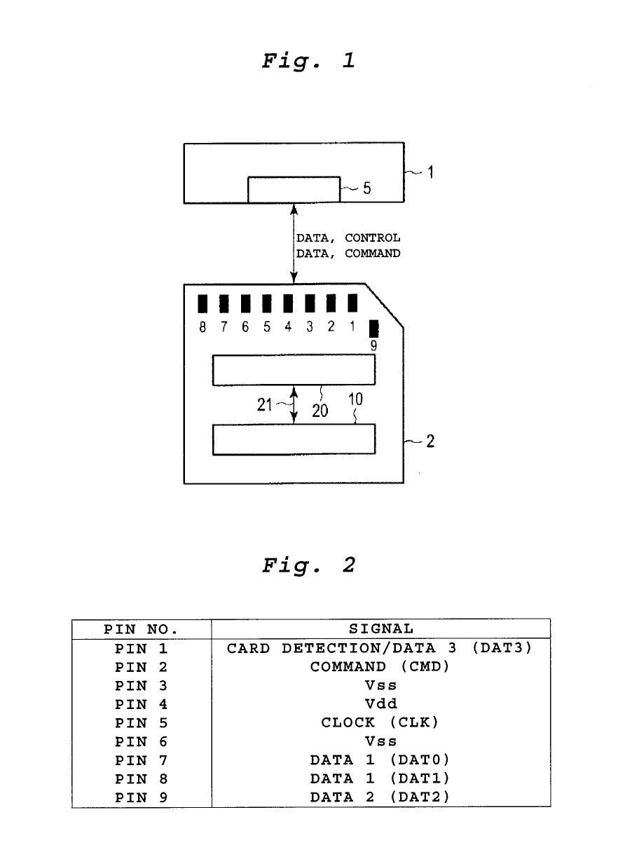

In the following, host equipment 1 and the memory card 2 controlling it related to Embodiment 1 will be explained. FIG. 1 is a schematic diagram illustrating the memory system including the host equipment 1 and the memory card 2 related to the present embodiment. Here, as an example of the memory card, an SD™ memory card (hereinafter to be referred to as memory card 2) is presented.

The host equipment 1 has a host bus interface 5 (hereinafter to be referred to as host bus 5). This host bus 5 is used to transfer the control data, logic address, and SD command to the memory card 2. That is, the host equipment 1 can control the memory card 2.

Also, the host equipment 1 carries out transmission/reception of the user data (write data, read data) with the memory card 2. This host equipment 1 has hardware and software for carrying out access to the memory card 2.

The memory card 2 includes a NAND type flash memory 10 (also known as flash memory 10), a controller 20 that controls the NAND type flash memory 10, and a NAND interface (IF) (corresponding to the SD interface 21 to be explained later, as well as metal pins 1 to 9 shown in FIG. 1) that carries out transmission/reception of the control data, SD command, and the data, etc.

The memory card 2 has power supplied to it when it is connected with the host equipment 1, and it is thus turned on to perform operations requested by the host equipment 1. More specifically, upon the request of the host equipment 1, data are stored in the NAND type flash memory 10, and the stored data are then read and output to the host equipment 1.

In this way, the host equipment 1 and the memory card 2 can be connected with each other so that it is possible to perform the two operations: the operation of data write/read and erasure with respect to the NAND type flash memory and the operation of reading data from the NAND type flash memory to the host equipment 1.

In the following, an example of the constitution of the host equipment 1 and the memory card 2 will be explained with reference to FIG. 1.

### (1-1. About the Host Equipment 1)

As explained above, the host equipment 1 outputs the control data, the SD command, the address, the user data, etc., to the memory card 2. In the following, the user data will be explained. For the host equipment 1 in the present embodiment, when the presence of an idle capacity at the tail of the last page of an en bloc write of user data is recognized based on the data size of the user data transferred to the memory card 2 and the page size of the memory cell array (to be explained later), in addition to the user data, other data, such as the data sequence including that of continuous “1” data (hereinafter to be referred to as Null data) are also output via the host bus 5 to the memory card 2. On the other hand, when it is found that there is no idle capacity at the tail of the last page, the Null data are not generated, and the user data free of the Null data are output to the memory card 2.

Also, the MPU 22 (to be described later) notifies the host equipment 1 of the page size of the memory card 2. The “1” data sequence has a designated data length.

### (1-2. About the Configuration of the Memory Card 2)

As explained above, the memory card 2 has an interface IF for performing the exchange of information (user data, address, SD command, control data, etc.) with the host bus 5 of the host equipment 1.

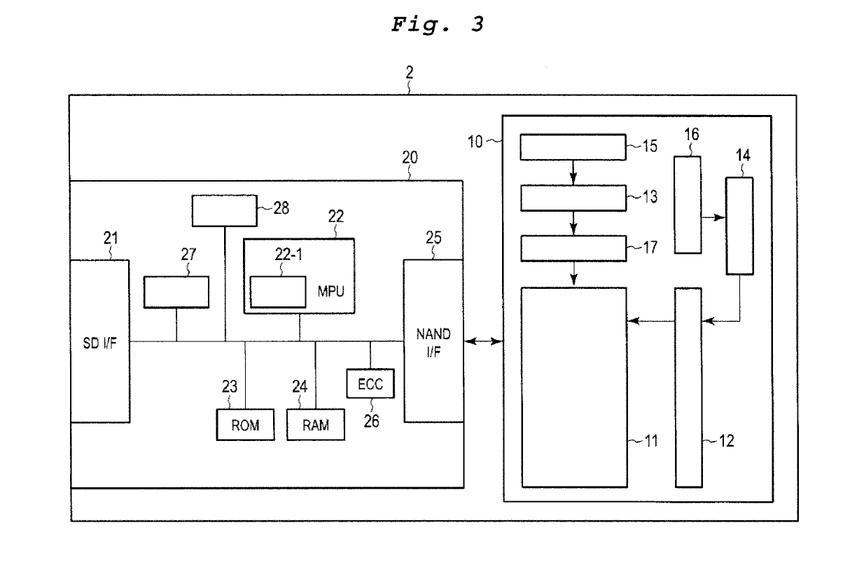

The memory card 2 is formed so that it can be inserted into or pulled out of a slot formed on the host equipment 1. As the memory card 2 is inserted in the host equipment 1, the multiple signal pins are electrically connected with the controller 20. For example, FIG. 2 shows the allotment of the signals to the first through ninth pins. FIG. 2 is a list of the first through ninth pins and their corresponding allotted signals in one embodiment.

Data 0 through 3 are allotted to the seventh, eighth, ninth and first pins, respectively. In addition, the card detection signal is also allotted to the first pin. Furthermore, the SD command is allotted to the second pin, the ground potential Vss is allotted to the third pin and the sixth pin, the power supply potential Vdd is allotted to the fourth pin, and the clock signal is allotted to the fifth pin.

The host controller (not shown in the figure) disposed in the host equipment 1 carries out communication of various types of signals and data with the controller in the memory card 2 via the first pin through the ninth pin. For example, when data are written in the memory card 2, the controller arranged in the host equipment 1 sends a write command as a serial signal via the second pin to the controller 20. In this case, the controller 20 answers the clock signal fed to the fifth pin, and fetches the write command sent to the second pin.

Here, as explained above, the write command uses only the second pin to be input as a serial signal to the controller 20. As shown in FIG. 2, the second pin allotted to input of the SD command is arranged between the first pin for data 3 and the third pin for ground voltage VSS. The multiple signal pins and their corresponding host bus interface 5 are used for communication between the host controller within the host equipment 1 and the memory card 2.

On the other hand, communication between the flash memory 10 and the controller 20 is carried out using the NAND bus interface (hereinafter to be referred to as NAND bus) 25 for the NAND type flash memory to be explained later. Consequently, although not shown in the figure here, the flash memory 10 and the controller 20 are connected with each other by, for example, 8-bit input/output (I/O) lines.

For example, when data are written to the flash memory 10 by the controller 20, the controller 20 sequentially inputs the following signals via the I/O lines to the flash memory 10: data input command 80H, column address, page address, data, and program command 10H (or cache program command 15H). Here, “H” in the data input command 80H refers to hexadecimal. It actually sends the 8-bit signal “10000000” in parallel to the 8-bit I/O lines. That is, with the NAND bus interface 21, multiple-bit NAND command is sent in parallel.

Also, with the NAND bus interface 25, the NAND command and the data can share the same I/O lines in carrying out communication with the flash memory 10.

In the following, the configuration of the NAND flash memory 10 and controller 20 included in the memory card 2 will be explained in more detail with reference to FIG. 3.

### (1-1-1. About the Configuration of the Controller 20)

First of all, the controller 20 will be explained with reference to FIG. 3. As shown in FIG. 3, the controller 20 includes an SD interface 21 (denoted as SD I/F 21 in the figure), an MPU (micro processing unit) 22, a ROM (read-only memory) 23, a RAM (random access memory) 24, an NAND interface 25 (denoted as NAND I/F 25 in FIG. 3), an ECC circuit 26, a register 27, and an encoder 28. These parts are formed integrated on the same semiconductor substrate. Here, the NAND flash memory 10 and controller 20 can be formed on the same semiconductor substrate, or on different semiconductor substrates, respectively.

The SD interface 21 carries out interface processes between the controller 20 and the host equipment 1. As explained above, the SD interface 21 receives, for example, the SD command, the (logic) address, the write data, etc., from the host equipment 1 via the host bus 5. Next, the SD interface 21 sends the received SD command to the MPU 22, and has the (logic) address and the write data stored in the RAM 24. In addition, the SD interface 21 outputs the read data to the host equipment 1 under the command of the MPU 22.

The MPU 22 controls the overall operation of the memory card 2. More specifically, when power supply is received by the memory card 2, the MPU 22 reads the firmware (a control program) stored in the ROM 23 and sends it to the RAM 24, then forms various types of tables in the RAM 24 by carrying out the designated operation. Also, the MPU 22 receives the write command, read command and erase command from the host equipment 1, then executes the designated operation for the NAND flash memory 10.

In addition, MPU 22 controls the operation of the NAND flash memory 10 under the command of the host equipment 1. More specifically, it controls the operation of data write, read, and erasure for the NAND flash memory 10, and it also carries out error correction for the read data and parity generation for the write data, etc. Consequently, the MPU 22 controls the physical state of the NAND flash memory 10 (such as the fact that a certain number of the logic sector address data should be contained in the physical block address at a certain site, or that the block at a certain site should be set in the erasure state, etc.).

As shown in FIG. 3, the MPU 22 has a monitor part 22-1. The monitor part 22-1 checks whether there exists a continuous “1” data sequence over a designated value in the write data temporarily stored in the RAM 24 and fed from the host equipment 1. For example, when the monitor part 22-1 determines that a continuous “1” data sequence over a designated value exists in the write data (data A, data B to be explained later), the MPU 22 determines that this continuous “1” data sequence is a Null data (Null region). In this case, on the basis of the data group including the management data to be explained later (such as the defective information of each page held in the memory cell array 11, etc.) and the user data, the MPU 22 generates the parity bit, and it stores the generated parity information in the region containing the Null data, and it then sends the write data including (user data+extended parity) to the NAND flash memory 10.

On the other hand, when monitor part 22-1 determines that the continuous “1” data sequence over a designated value is not contained in the write data (data C to be explained later), the MPU 22 writes the user data sent from the host equipment 1 to the memory cell array 11 according to the address obtained by LP conversion (logic-physical conversion). In addition, while executing the write of data A, B and C, the MPU 22 uses the encoder 28 to perform scrambling of the user data. The scrambling of the user data will be explained later.

In addition, when a data read instruction is received from the host equipment 1, the MPU 22 determines which parity should be used to perform the error correction. That is, when the normal parity and extended parity are generated, it determines whether the extended parity should be used to perform the error correction or the normal parity should be used to perform the error correction by selecting the type of the parity with a longer bit length of the parity bit. In addition, the MPU converts the extended parity among the written data sequence (user data+extended parity) to the original “1” data sequence, then sends the (user data+“1” data sequence) to the host equipment 1.

The ROM 23 stores the control program, etc., controlled by the MPU 22.

The RAM 24 is used as the operation area of the MPU 22 for storing the control program and various types of tables (Tables). More specifically, the logic-physical conversion table is held in the RAM 24. The logic-physical conversion table has the logic address sent from the host equipment 1 converted to the physical address indicating where the address should be written in the memory cell array 11. The logic-physical conversion table lists the value each time that a change takes place corresponding to the state of use of the block BLK of the memory cell array 11.

The NAND interface 25 carries out interface treatment between the controller 20 and the NAND flash memory 10. That is, under the command from the MPU 22, the NAND interface 25 outputs the commands issued from the MPU 22 (write command, read command, erasure command, etc.), the physical address, and the write data, etc., to the I/O buffer 15. In addition, it receives the read data sent from the I/O buffer 15, and transfers them to the RAM 24.

The ECC circuit 26 carries out error correction for the data. More specifically, for the page data read from the NAND flash memory 10, the ECC circuit 26 carries out error detection. When an error is detected, it carries out error correction. In addition, in the case of data write, on the basis of the write data, it generates the parity (normal parity) needed for error correction and, on the basis of the data group including the write data and the management data, it generates the extended parity needed for error correction.

The register 27 has various types of registers, such as CSR, CID, RCA, DSR, CSD, SCR, OCR, etc.

The encoder 28 carries out a scramble treatment for the write data. As to be explained later, it uses a pseudo random number generator and a scramble circuit to generate the random number.

### (1-1-2. About the Configuration of the NAND Flash Memory 10)

In the following, the NAND flash memory 10 will be explained with reference to FIG. 3. As shown in the figure, the NAND flash memory 10 includes a memory cell array 11, a row decoder 12, page buffer 13, voltage generator 14, I/O buffer 15, control part 16 and a sense amplifier 17. They are formed integrated on the same semiconductor substrate.

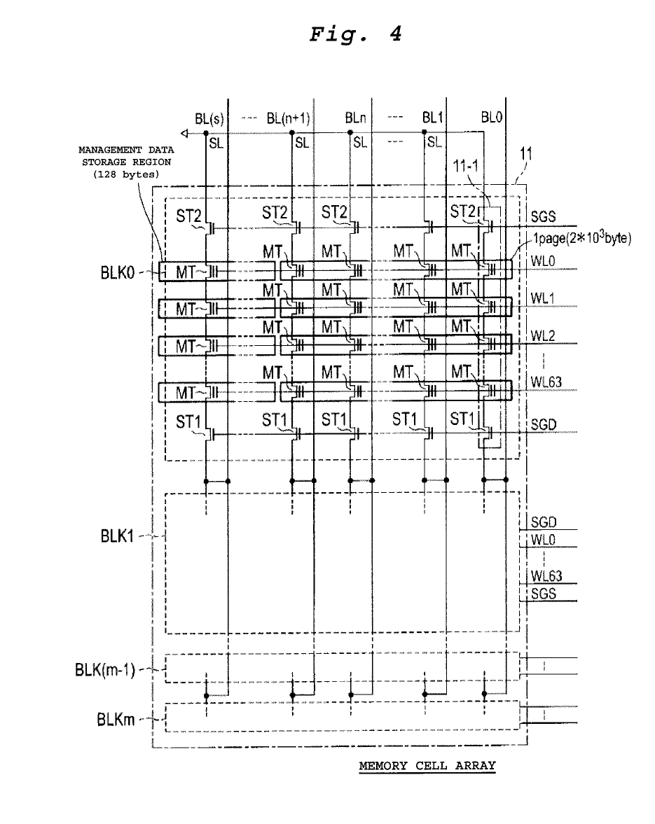

The memory cell array 11 has multiple memory cell transistors MT. The memory cell transistors MT store the user data, the extended parity, and the management data (such as the normal parity and the defective information of the page unit, etc.) sent from the host equipment 1. In the following, the configuration of the memory cell array 11 will be explained with reference to FIG. 4.

As shown in the figure, the memory cell array 11 has multiple blocks BLK (BLK0 to BLKm (m is a natural number of 1 or larger)), and each of these blocks BLK0 to BLKm have multiple NAND strings 11-1. Each of the NAND strings 11-1 has, for example, 64 memory cell transistors MT and selecting transistors ST1, ST2. The NAND strings 11-1 are connected to the corresponding bit lines BL.

There are, for example, 2×10³×8 bit lines BL0 to BL(n+1) in all. There are, for example, 128 lines in all for the bit lines BL(n+2) to BL(s). Consequently, the number of NAND strings 11-1 corresponds to the number of bit lines BL arranged in the memory cell array 11. As explained above, the NAND strings 11-1 shown in FIG. 4 hold the user data sent from the host equipment 1 and the extended parity generated by the ECC circuit 26, and the NAND strings 11-1 connected with the bit lines BL(n+2) to BL(s) hold the management data (in the following, the region holding the management data will be referred to as the management data storing region).

Each of the memory cell transistors MT that form the NAND strings 11-1 is an FG type N-channel MOS transistor having a charge storage layer (such as a floating gate) formed via a gate insulating film on the semiconductor substrate, as well as a control gate formed via an inter-gate insulating film on the charge storage layer. Also, the memory cell transistors MT may have a MONOS structure where the charge storage layer is made of an insulating substance. Also, the number of the memory cell transistors MT in the NAND strings 11-1 is not limited to 64. The number may also be 8, 16, 32, 128, or 256, etc. There is no specific restriction on the number. In the NAND strings 11-1, the memory cell transistors MT adjacent to each other share the source and drain. Then, between the selecting transistors ST1, ST2, the current route is arranged to make serial connection. For the serial connected memory cell transistors MT, the drain region on one end side is connected with the source region of the selecting transistor ST1, and the source region on the other end side is connected with the drain region of the selecting transistor ST2.

The control gates of the memory cell transistors MT on the same row are commonly connected with certain of the word lines WL (WL0 to WL63), and the gate electrodes of the selecting transistors ST1, ST2 of the memory cell transistors MT on the same row are commonly connected with the select gate lines SGD, SGS, respectively. In addition, the drains of the selecting transistors ST1 on the same row in the memory cell array 11 are commonly connected with certain of the bit lines BL (BL0 to BLn (n is a natural number of 2 or larger)). The sources of the selecting transistors ST2 are commonly connected with the source line SL. The data are written en bloc to the multiple memory cell transistors MT connected with the same word line WL. This unit is called a page. In addition, erasure of data is carried out in units of block BLK. In the embodiment, each page is a unit that can hold 2×10³×8 bit data.

### (1-1-1-1. About the Threshold Distribution of Memory Cell Transistors MT)

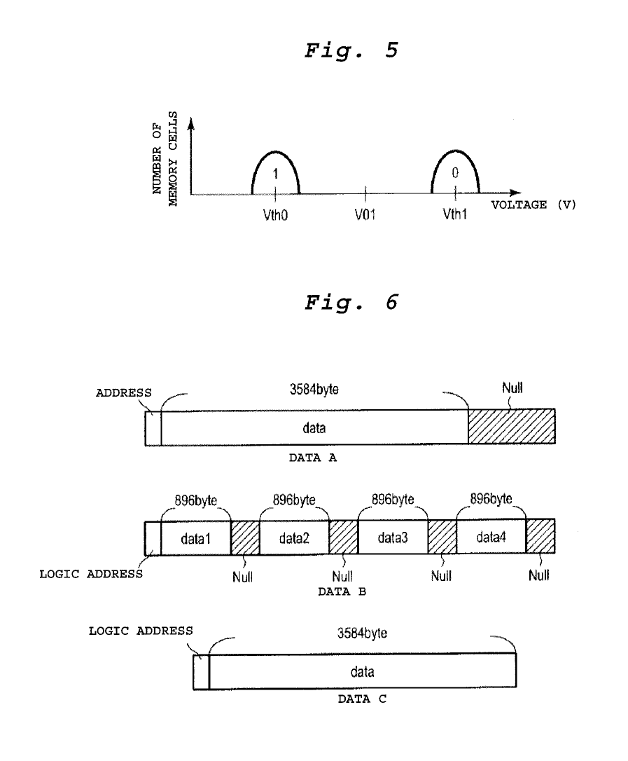

In the following, the threshold distribution of the memory cell transistors MT will be explained with reference to FIG. 5. FIG. 5 is a graph illustrating the threshold distribution (abscissa) versus the number of the memory cell transistors MT (ordinate). As shown in the figure, each of the memory cell transistors MT can hold a binary (2-levels) data (1-bit data). That is, the memory cell transistors MT can hold two types of data of 1 and 0 sequentially in the rising order of the threshold voltage Vth. That is, the “1” data sequence is a data sequence indicating the state when the threshold voltage Vth is low.

For the threshold voltage Vth0 of data 1 in the memory cell transistors MT, there is the following relationship: Vth0<V01. For the threshold voltage Vth1 of data 0, there is the following relationship: V01<Vth1. In this way, the memory cell transistors MT can hold the 1-bit data of data 0 and data 1 corresponding to the threshold. The threshold voltage varies as the electric charge is injected into the charge storage layer. Also, the memory cell transistors MT may hold the data of 4 or more levels of values.

### (1-1-2. About the Peripheral Circuit)

Now, return to FIG. 3 to continue the explanation of the peripheral circuit.

In the data write operation, read operation and erasure operation, the row decoder 12 selects the row direction of the memory cell array 11 on the basis of the row address sent from the controller 20 via the I/O buffer 15. That is, the row decoder 12 selects the word line WL and select gate lines SGD, SGS. Memory cell array 11 then transfers appropriate voltage to the word line WL and select gate lines SGD, SGS.

In the data write operation, the page buffer 13 sends the write data (user data, normal parity, and extended parity bit) sent from the I/O buffer 15 to the sense amplifier 17. Also, in the data read operation, the data read from the sense amplifier 17 (user data and extended parity data) are temporarily stored and then output to the I/O buffer 15.

The sense amplifier 17 selects the bit line BL, reads the data of the memory cell transistors MT, and sends the read data to the page buffer 13. More specifically, the data of the memory cell transistors MT connected with the word line WL are selected by the row decoder 12. In addition, in the data write mode, the data sent from the page buffer 13 are written in the memory cell transistors MT selected by the row decoder 12.

The voltage generator 14 generates the voltage needed for the data write operation, erasure operation and read operation under control of the control part 16. The generated voltage needed for the operations is fed to the row decoder 12 and sense amplifier 17.

In the data write operation, the I/O buffer 15 temporarily stores the write data, address, and write command sent from the controller 20. The address is then sent to the row decoder 12 and the address and the write command are sent to the control part 16, while the write data are sent to the page buffer 13. Also, in the data read operation, the address and the read command are received. The address and the read command are then sent to the control part 16, and the address is sent to the row decoder 12. Also, the read data received from the page buffer 13 are output to the controller 20.

In the following, the control part 16 will be explained. Here, the control part 16 controls the overall operation of the NAND flash memory 10. That is, on the basis of the address and the command sent from the controller 20, the sequence needed for the data write operation, read operation and erasure operation is executed.

### (2. About the Format of the Write Data)

In the following, the format of the write data sent from the host equipment 1 to the memory card 2 will be explained with reference to FIG. 6. As shown in FIG. 6, in the format of the write data output from the host equipment 1, there are 3 types, that is, data A, data B, and data C.

### (2-1. Data A)

The frame format of the data A shown in FIG. 6 is generated by the host equipment 1 when it is recognized so that there exists an idle capacity at the tail of the last page where the user data are written, as determined from the data size of the user data sent by the host equipment 1 to the memory card 2 and the page size of the memory cell array (to be explained later).

The data A have a frame format including the following data sequentially from the head: logic address, user data, and Null data. That is, the logic address is set at the head, followed by the user data (such as 1 piece of video data), then the Null data sequence for transmission. The user data have a data size of, for example, 3584 bytes. When the data A are written in the memory cell array 11, first of all, in the RAM 24, the Null region is replaced with the extended parity, then the data sequence including the user data and the extended parity is written in the NAND flash memory 10. In other words, from the memory cell transistors MT corresponding to the logic address, for example, the user data are written into the 3584×8 continuous memory cell transistors MT, then the extended parity is written in the memory cell transistors MT.

### (2-2. Data B)

The data B have a format which has the logic address at the head, followed by multiple consecutive groups each having the user data and the Null data after the user data (user data+Null data). That is, the data B includes the following data sequentially: user data, Null data, user data, Null data. (In FIG. 6, “data1”, “data2”, . . . “data3”, “data4”. When these “data1” to “data4” are not distinguished from each other, they are simply referred to as “data”). When the data B are written in the memory cell array 11, first of all, in the RAM 24, the Null region is reloaded to the extended parity. Then, it is written in the NAND flash memory 10. That is, the memory cell transistors MT corresponding to the logic address is set at the head, and, in each of the pages, the data sequence including user data and extended parity is stored. In addition, in the case of the data sequence of data A, B, the normal parity is generated in addition to the extended parity.

### (2-3. Data C)

Data C have a frame format without setting the Null data annexed to the “data” in the frame format of the data A. For this frame format, from the memory cell transistors MT corresponding to the logic address, for example, the user data are written in, for example, 3584×8 continuous memory cell transistors MT, and the extended parity is not generated. In this case, the normal parity generated on the basis of the “data” is stored in the storing region of the management data.

According to the present embodiment, an example can be presented to explain that the video data with an original data size of 3584 bytes are sent in the frame format of data A.

### (2-3. Dividing Method of Write Data)

In the following, the dividing method of the write data by MPU 22 will be explained with reference to FIG. 6. Here, it is assumed that the MPU 22 knows the page size (hereinafter to be referred to as P). Here, the case in which a piece of the video data is written in the memory cell array 11 will be presented as an example. Given the data capacity of the video data is D, and the user area capacity of 1 page unit is P, the storage page number m needed can be represented by formula (1).

m=RoundUp(D/P,0) (1)

The function RoundUp is a function used in rounding up the data. Here, suppose the portion after the decimal point is rounded up. That is, for example, for D/P=1.5, as 1.5 is a value larger than 1 and smaller than 2, one has RoundUp (1.5,0)=“2”.

Then, using the “m” obtained in formula (1), the capacity p of the write data stored in each page can be obtained using formula (2).

p=RoundUp(D/m,0) (2)

The user area capacity of 1 page is P as mentioned previously. Among the P, the user data quantity is p, so that the data capacity r of the extended parity written in each page becomes formula (3).

r=P−p (3)

According to the formulas (1)-(3), suppose the data capacity for data 1 to data 4 is p, and the data capacity for the Null region is r, the frame format sent by host equipment 1 to the memory card 2 is composed of the combination of (p+r).

In the following, specific numeric values will be substituted in the formulas (1)-(3) for explanation.

Suppose the data capacity of a photographic picture D=3584 bytes, the user area capacity of 1 page P=1024 bytes, according to the formulas (1)-(3), one has m=RoundUp (3584/1024, 0)=4, p−RoundUp (3584/4, 0)=896 bytes, r=1024−896=128 bytes. In this case, when the frame format of data A is sent from the host equipment 1, by dividing the data sequence as mentioned previously, the data sequence (the data group including the user data and the Null data) stored in 1 page by the frame format shown in data B is generated.

The operation may also be carried out by the host equipment 1. That is, as the frame format of data A is sent from the host equipment 1, the data are divided by the MPU 22 using the method. However, one may also adopt a scheme in which the host equipment 1 carries out the computing operation to generate the frame format of data B, then sends it to the memory card 2.

### (2-4. Parity Generation Method)

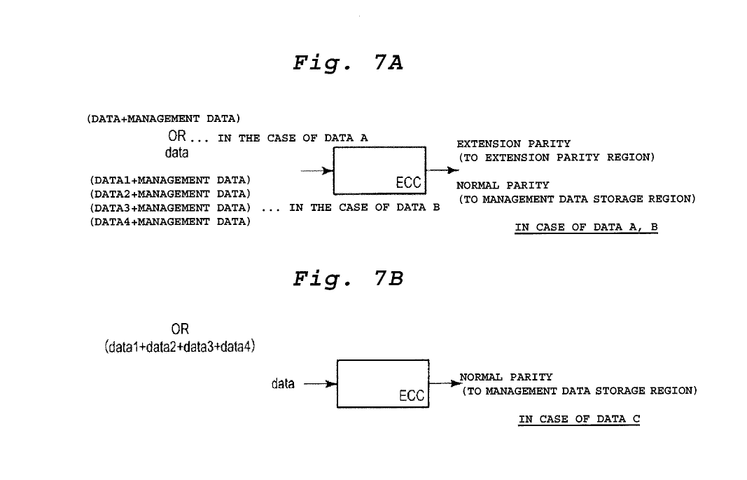

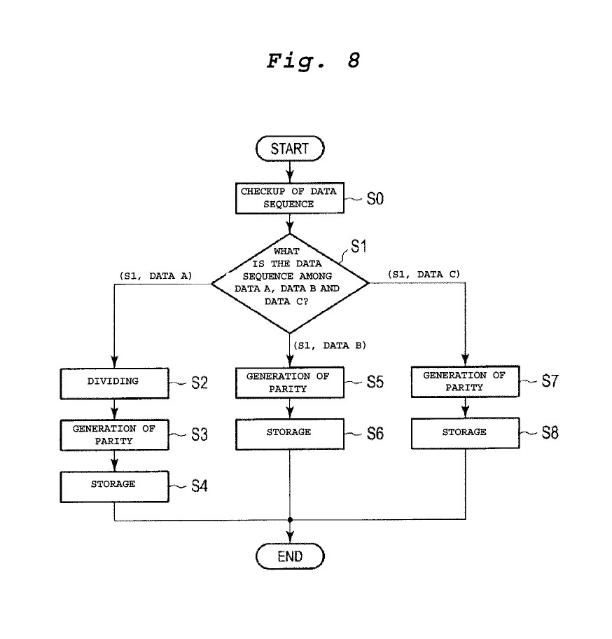

In the following, generation of the parity bit by the ECC circuit 26 will be explained with reference to FIG. 7A, FIG. 7B, and FIG. 8. Here, the parity bit refers to the data sequence that carries out error correction for the read data as mentioned previously, and it is generated by the ECC circuit 26 when the user data are written.

FIG. 7A shows the parity bit generated by the ECC circuit 26 when the host equipment 1 sends the data A and data B. FIG. 7B shows the parity bit generated by the ECC circuit 26 when the host equipment 1 sends the data C. In addition, FIG. 8 is a flow chart for the method for generating the parity bit by the ECC circuit 26.

First of all, the data sequence stored in the RAM 24 is checked by the monitor part 22-1. That is, it checks whether they are data A, data B, or data C (in FIG. 8, step S0). If the result obtained in step S0 is that the frame format of the stored data sequence is data A (FIG. 7A, FIG. 8: (S1, data A)), the data sequence is divided into multiple data sequences according to the formulas (1) to (3) (FIG. 8, S2). Then, on the basis of the data group including the divided data sequence and the management data, the extended parity is generated, and, on the basis of these divided data sequences, the normal parity is generated (S3). That is, for data A, as shown in FIG. 7A, in addition to the normal parity, the extended parity bit is generated by the ECC circuit 26 on the basis of the data sequence as a combination of the various user data (in FIG. 6, “data1” to “data4”) and their corresponding management data. More specifically, the extended parity is generated on the basis of the data sequence including the group of the “data1” and the “management data” that store the management information of the page where the “data1” is stored. Then, the same operation is carried out for the “data2” and thereafter. As explained above, the extended parity is stored in the Null region of data B. As a result, the extended parity is stored in the tail of each page, and the normal parity is stored in the management storage region (FIG. 8, S4). In addition, aforementioned, the stored data quantity is r.

On the other hand, if the result of step S0 indicates that the frame format of the stored data sequence is data B (FIG. 7A, FIG. 8: (S1, data B)), the generated extended parity is stored in the region of the Null data (S5). Then, according to the physical address, the user data and the extended parity are stored in the various pages in the memory cell array 11 (S6). Just as the step S3, the generated normal parity is stored in the management data storage region.

On the other hand, if the result of step S0 indicates that the frame format of the data sequence stored in the RAM 24 is data C (FIG. 7B, FIG. 8 (S1, data C)), the data sequence is not divided, and the normal parity is generated on the basis of the user data for each page unit (S7). Then, according to the logic address, the user data are stored in the corresponding memory cell array 11 (S8), and the normal parity is stored in the management data storage region.

(3. Schematic Diagram Illustrating the Case in which the User Data and the Extended Parity are Stored in the Memory Cell Array 11)

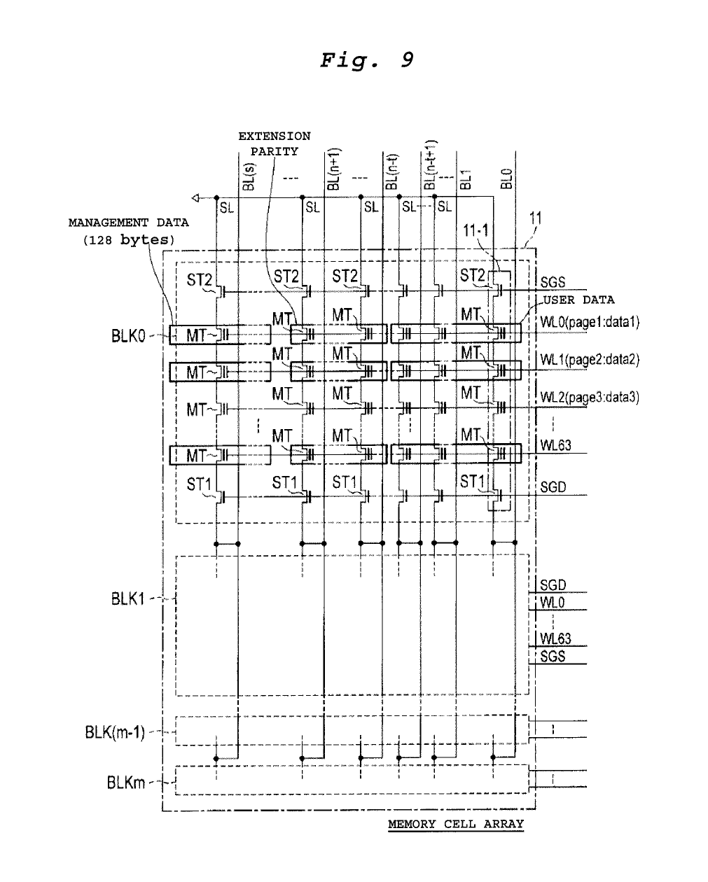

FIG. 9 is a schematic diagram illustrating the user data (“data1” to “data4”) and the extended parity stored in the memory cell array 11 when the frame format sent from the host equipment 1 is data A or data B. As shown in FIG. 9, on the page corresponding to the word line WL0 (denoted as page 1 in FIG. 9), “data1” is stored in the memory cell transistors MT connected with the bit lines BL0 to BL(n−t−1), and the extended parity is stored in the memory cell transistors MT connected with bit lines BL(n-t) to BL(n+1). Similarly, on the page corresponding to word line WL1 (denoted as page2 in FIG. 9), for example, “data2” is stored in the memory cell transistors MT connected with the bit lines BL0 to BL(n−t−1), and the extended parity is stored in the memory cell transistors MT connected with bit lines BL(n−t) to BL(n+1). Here, an example in which “data1” and “data2” are stored in the pages corresponding to word lines WL0, WL1. In addition, “data3” and the corresponding extended parity are stored in the page corresponding to word line WL2, and “data4” and the corresponding extended parity are stored in the page corresponding to word line WL3. As mentioned previously, for the “data”, the normal parity and the extended parity are stored corresponding to each word line WL.

### Effects of Embodiment 1

By means of the host equipment 1 and the memory card 2 controlled by it related to the present embodiment, it is possible to improve the error correction for the read data. As explained above, according to the present embodiment, the data (such as a piece of photographic data) sent from the host equipment 1 and stored in each page of the memory cell array 11 does not have the maximum capacity of 1 page (such as 1024 bytes). Instead, an area that can store the extended parity is left on each page, while the user data are stored. That is, an area for storing “r” is arranged for each page as mentioned previously, and the extended parity is stored in the storing area. Here, in addition to the normal parity stored in the management data, generation of the extended parity can also improve error correction of the ECC circuit 26 in the read operation. As a result, when correction treatment is carried out for the read data, it is possible to selectively use a certain parity.

When data are read, as far as the question as to which of the normal parity and the extended parity should be used is concerned, the parity with a higher correction ability, that is, with a longer parity bit, is used. In order to improve error correction of the ECC circuit 26, the bit number of the extended parity is larger than the normal parity. However, in some cases, although an area for storing the extended parity is set for the page, the normal parity nevertheless has a larger bit number. In such a case, the normal parity should be used.

According to the host equipment 1 and the memory card 2 under its control related to the present embodiment, it is possible to average the error correction for correcting the read data. According to the present embodiment, as shown in FIG. 9, the extended parity with the same capacity is stored in each page. That is, when error correction is carried out using the extended parity, because there is no dispersion in the length of the extended parity on the various pages, when read is carried out for the user data stored in each page, the memory card 2 has uniform error correction in the read operation of the various pages.

### Modified Example 1

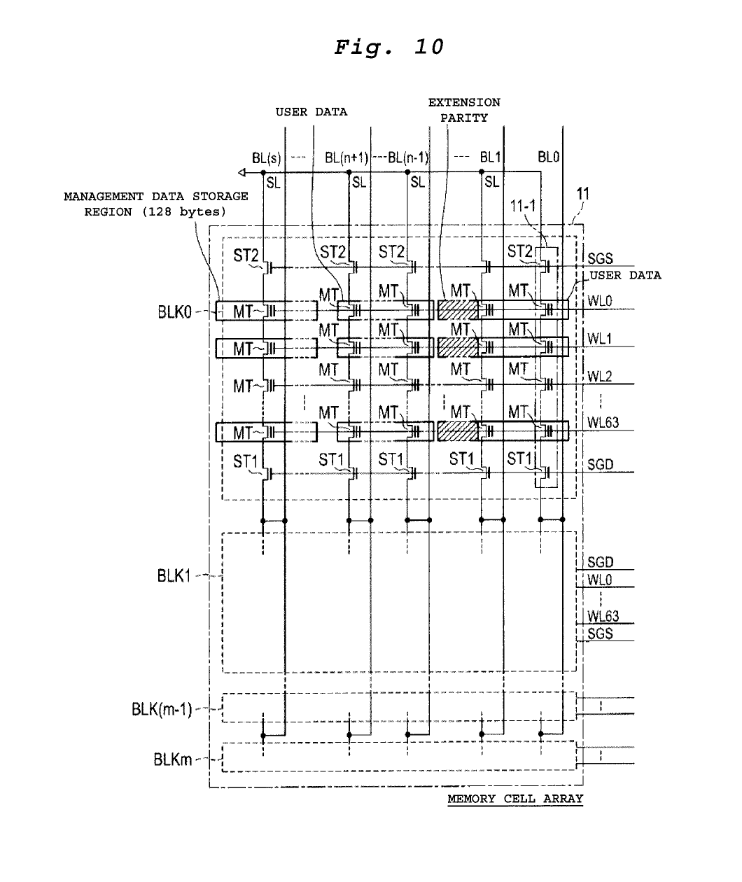

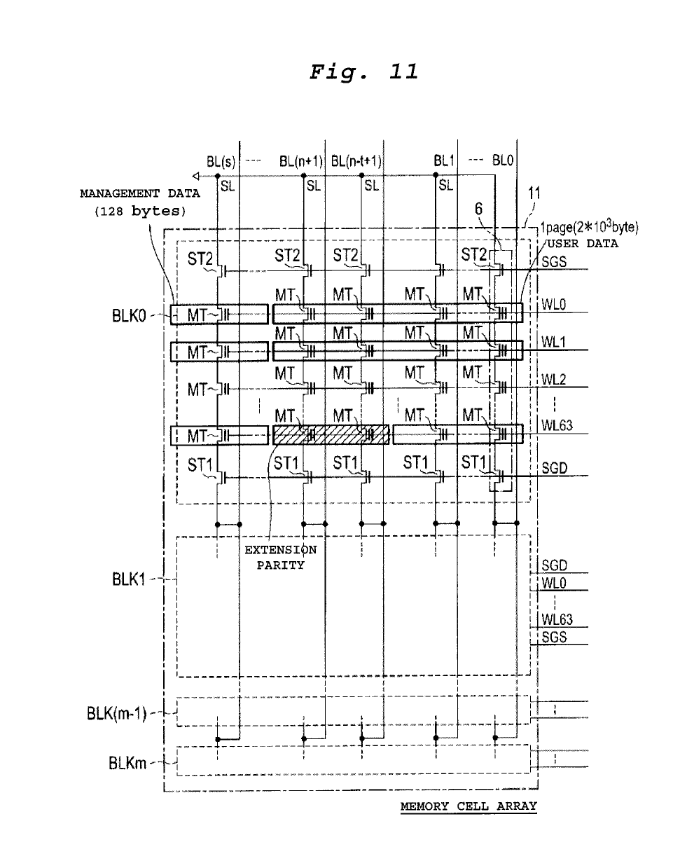

In the following, the constitution of the host equipment 1 and the memory card 2 under its control related to a modified example (hereinafter to be referred to as Modified Example 1) of the Embodiment 1 will be explained with reference to FIG. 10. In this example, for the host equipment 1 and the memory card 2 under its control, as a result of incorporation of the frame format of data B in the memory card 2, on each page, the Null region is held in the user data (“data”). In the Embodiment 1, the host equipment 1 knows the page capacity of the memory cell array 11, so that the host equipment 1 sets the logic address of the Null region to ensure that the Null region can be stored at the tail of each page. However, in Modified Example 1, it is assumed that the host equipment 1 does not know the page capacity of the memory cell array 11. On the other hand, the portion of the configuration that is the same as that already stated will not be explained again.

### (MPU 22)

The MPU 22 in Modified Example 1 works as follows: when there are Null data continuous for a designated bit number (that is, continuous “1” data sequence) in the write data, if it is found that as a result of the write operation, the Null data stored in each page is held in the user data, after the write operation in the NAND flash memory 10, the physical address of the Null data before the write operation and the physical address of the user data are changed so that the parity is stored at the tail of each page. As a result, the frame format of data A explained above in Embodiment 1 is formed. This operation is carried out in the RAM 24.

FIG. 10 is a schematic diagram illustrating the case in which the MPU 22 carries out write of the user data and the extended parity without changing the physical address of the extended parity. As shown in FIG. 10, the extended parity generated on the basis of the user data and the management data is stored in the bit lines BL2 to BL(n−2), and the write data are stored on its two sides. In such a case, before write of the user data and the extended parity in the memory cell array 11, the MPU 22 changes the physical addresses of the Null data and one of the user data. In this way, for MPU 22, the physical address of the Null region that has been sent is shifted to the tail as shown in FIG. 8, then the write data and the extended parity are stored in the memory cell array 11.

### Effects of Modified Example 1

With the host equipment 1 and the memory card 2 under its control related to Modified Example 1, the same effects as those in the Embodiment 1 also can be realized. That is, even when the position of the Null data in the frame format sent from the host equipment 1 shifts, by changing the physical address as mentioned previously, it is possible to realize the same effect as that shown in FIG. 9 in the Embodiment 1. As a result, even in Modified Example 1, it is still possible to improve the correction ability in the read of data stored in each page, and it is possible to improve error correction free of dispersion among different pages.

### Modified Example 2

In the following, the host equipment 1 and the memory card 2 under its control related to Modified Example 2 with respect to the Embodiment 1 (hereinafter to be referred to as Modified Example 2) will be explained with reference to FIG. 11. The same features as those in the constitution will not be explained again. As mentioned previously, the extended parity generated by the ECC circuit 26 is generated with respect to the data group composed of (the user data of each page+the corresponding management data). However, it may also be generated only with respect to the entire user data. More specifically, when the frame format sent from the host equipment 1 is data A, instead of dividing the “data” (such as 3584 bytes in FIG. 6) into “data1” to “data4”, the extended parity may be generated on the basis of the one “data”. When MPU 22 determines that the idle capacity on the last page where the user data are stored (the Null data should have been stored in this area) is sufficient, and that error correction is even better than that when the correction treatment is carried out using the normal parity, just as in the case of the reception of data B, the extended parity is generated in addition to the normal parity. That is, when MPU 22 receives the frame format of the data A from the host equipment 1, the extended parity may be generated as shown in Modified Example 2.

In this case, the ECC circuit 26 generates the extended parity on the basis of the user data temporarily stored in the memory card 2 (RAM 24). The MPU 22 has the generated extended parity buried in the Null region, and it then has such data sequence written in the NAND flash memory 10.

In the following, this case will be explained with reference to FIG. 11. FIG. 11 is a schematic diagram illustrating that the user data and the extended parity corresponding to it are stored in the memory cell array 11. As shown in FIG. 11, the user data are stored in the various pages corresponding to word lines WL0 to WL62, and the memory cell transistors MT connected with the word line WL63 and bit lines BL0 to BL(n−t). Then, the extended parity is stored in the memory cell transistors MT connected with word line WL63 and bit lines BL(n−t+1) to BL(n+1).

As explained above, this extended parity is an extended parity generated on the basis of the user data stored in the memory cell array 11 shown in FIG. 11. When the user data are read, the extended parity is used to perform error-correction treatment, then the error-corrected user data are sent to the host equipment 1.

In this case, too, the normal parity is arranged in the management data storage region.

### Effects of Modified Example 2

With the host equipment 1 and the memory card 2 related to Modified Example 2, it is also possible to realize the same effects as those of the Embodiment 1. That is, it is possible to improve error correction when the data stored in each page are read.

### Embodiment 2

In the following, the host equipment 1 and the memory card 2 under its control related to Embodiment 2 will be explained. As explained above with reference to Embodiment 1, when the normal user data are stored in the memory cell array 11, the user data are randomized, then the randomized user data are stored in the memory cell array 11. According to Embodiment 2, after the user data are compressed using a designated method, the compressed data are randomized and then stored in the memory cell array 11. As to be explained later, the randomized user data are compressed (also explained below) and then are written in the memory cell array 11. In Embodiment 2 to be explained below, while it can be executed alone, it may also be combined with Embodiment 1 explained above for execution. Consequently, after compression of the user data, the extended parity is generated as needed. The same features as those in the Embodiment 1 will not be explained again.

### (1. MPU 22)

In the present embodiment as explained above, in addition to the monitor part 22-1, the MPU 22 also has a compressing part 22-2, a control part 22-3, and a management part 22-4. The monitor part 22-1 monitors the user data stored in the RAM 24 and determines whether a designated data sequence is contained in the user data. More specifically, the user data are divided into, for example, 4 bits, 8 bits, 4 bytes, etc. When dividing is carried out to the 4 bits, 8 bits, 4 bytes, etc., the data sequence is monitored for being the designated data sequence. If there is the designated data sequence in the write data, the control part 22-3 is notified.

Upon receiving the notification from monitor part 22-1, the control part 22-3 controls so that the compressing part 22-2 compresses the data sequence in the designated direction.

Upon receiving the instruction of compression from control part 22-3, the compressing part 22-2 compresses the user data stored in the RAM 24 using the designated method. In the following, the compression method by the compressing part 22-2 will be explained. In addition, the encoder 28 carries out randomizing of the compressed data.

The management part 22-4 finds out the original bit length of the user data stored in the memory cell array 11, and the physical address for storing the compressed data in the memory cell array 11.

### (1-2. Compression Method)

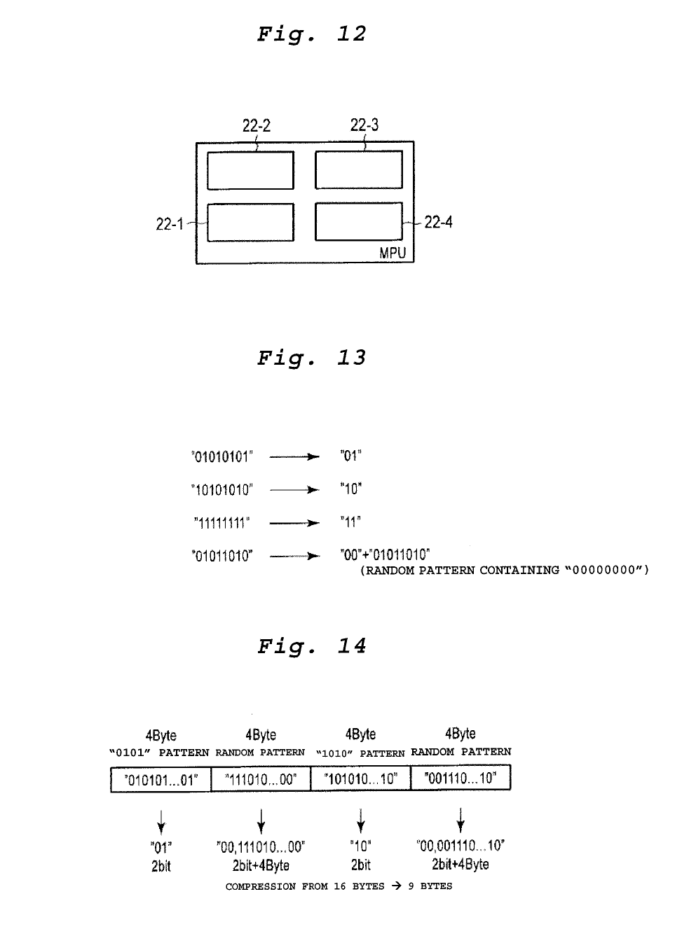

In the following, the compression method by the compressing part 22-2 will be explained with reference to FIG. 13. FIG. 13 shows the case in which the user data sent from the host equipment 1 are represented in 8-bit units. The compression method in this embodiment carries out compression as the short code in the bit pattern with a high generation frequency is allotted to the long codes in the low pattern.

For example, when a data sequence of “01010101” is to be sent from the host equipment 1, the compressing part 22-2 converts it to 2-bit “01”, that is, it makes compression. Similarly, when a data sequence of “10101010” is sent from the host equipment 1, the compressing part 22-2 compresses it to 2-bit “10”, and it compresses the sequence of “11111111” to the 2-bit “11”.

However, even for the 8-bit data sequence, for the pattern with a low generation frequency, the compression may not be possible to perform. Consequently, when compression is carried out in 8-bit units, if the monitor part 22-1 determines that the 8-bit data sequence is a random pattern with a low generation frequency, or the data sequence is “00000000”, these data sequences are not compressed. In addition, “00” is attached to the head, and the 8-bit sequence following the “00” is a random pattern or a sequence of “00000000”.

In the following, the method of compression of the user data when the user data of 16 bytes are divided into 4 byte parts will be explained with reference to FIG. 14. As shown in FIG. 14, for example, each time that 16 bytes are divided into 4-byte parts, the 16-byte data sequence is divided into the 4-byte data sequences with the pattern of “010101 . . . 01”, the pattern of “111010 . . . 00”, the pattern of “10101 . . . 10”, and the pattern of “001110 . . . 10”. As explained above, the monitor part 22-1 determines whether the designated pattern is contained in the divided data sequence.

Here, under control of control part 22-3, the compressing part 22-2 compresses the pattern of “010101 . . . 01” to the “01” pattern, compresses the pattern of “101010 . . . 10” to the “10” pattern. Also, as the pattern of “111010 . . . 00” is a random pattern, the compressing part 22-2 does not compress the data sequence, and “00” is attached to the head to a data sequence of “00”+“111010 . . . 00”. Then, for the pattern of “001110 . . . 00”, as it is also a random pattern, the data sequence is not compressed by compressing part 22-2, and, just as above, “00” is attached to form a data sequence of “00”+“001110 . . . 00”. As a result, the 16-byte data sequence is compressed to the 9-byte data sequence. The compressed data sequence may also be held in a region different from the region where the data sequence exists before compression, and it may also be stored in the region where the data sequence before compression are kept.

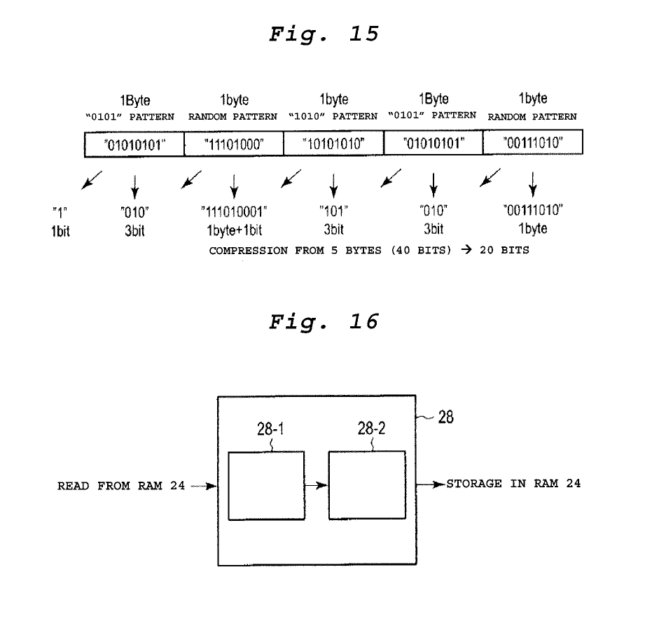

In the following, a compression system different from this system will be explained with reference to FIG. 15. Here, the divided data sequences each have 1 byte (8 bits). A brief account can be given on this compression system, that is, for the compressed data sequence, “1” is added and, different from it, for the non-compressed data sequence, “0” is added to the compressed data sequence. A detailed explanation will be made below with reference to FIG. 15.

As shown in FIG. 15, for the head sequence of “01010101”, it is possible to compress it to “01”. Consequently, “1” is attached to the head of this sequence of “01010101”. Then, for “11101000”, as compression cannot be made, “0” is attached to indicate that the data sequence is a non-compressed data sequence. That is, for the “01010101” sequence, by merging it with the succeeding data sequence, it can be compressed to “010”. Then, for the sequence of “10101010” succeeding the sequence of “11101000”, as it can be compressed, “1” indicating that this “11101000” can be compressed is added. That is, it becomes “111010001”. Then, in the same way as above, compression is carried out and the data sequence shown in FIG. 15 becomes “1”+“010”+“111010001”+“101”+“010”+“11011101”. That is, compression is made as 5 bytes (40 bits)=>20 bits.

### (2. Constitution of Encoder 28)

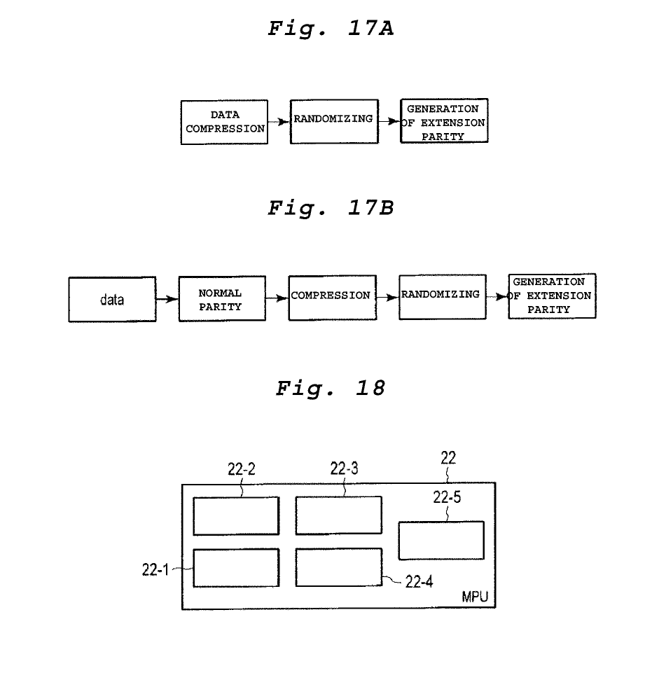

In the following, the encoder 28 will be explained with reference to FIG. 16. For the compressed data sequence as mentioned previously, the encoder 28 carries out a scramble treatment. As shown in detail in FIG. 16, the encoder 28 includes pseudo random number generator 28-1 and scramble circuit 28-2.

The pseudo random number generator 28-1 generates a pseudo random number on the basis of the seed value. The seed value is an intrinsic value of the memory card 2. For example, it may be the lot No. of the silicon wafer or the like when the MPU 22 is manufactured.

There is no specific restriction on the constitution of the pseudo random number generator 28-1. For example, a linear feedback shift register may be used. For example, the pseudo random number generator 28-1 generates the pseudo random number according to the command of the MPU 22.

In the data write mode, the scramble circuit 28-2 reads the compressed user data from the RAM 24, and it then scrambles on the basis of the pseudo random number generated by the pseudo random number generator 31. Then, the result of the arithmetic is stored as the scramble data in the RAM 24.

### (3. About the Sequence of Generation of the Extended Parity)

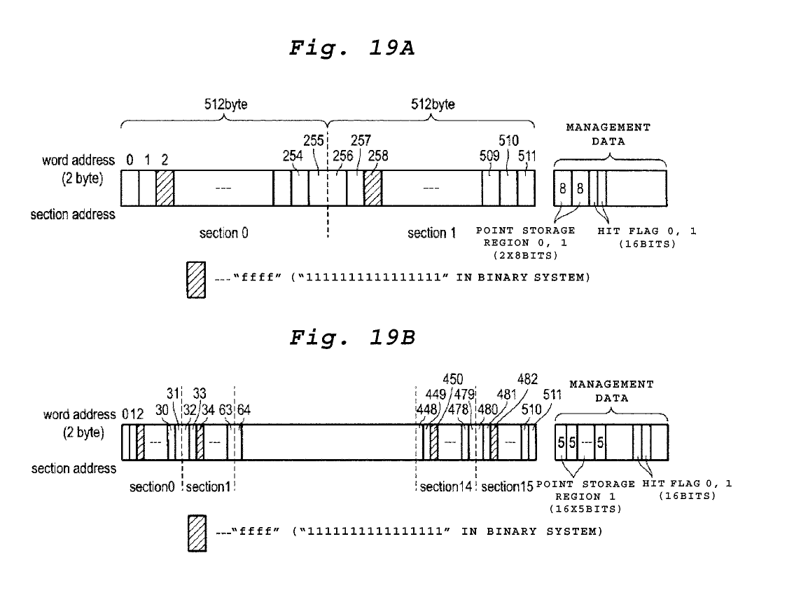

In the following, the procedure for the generation of the extended parity in Embodiment 2 will be explained with reference to FIG. 17A and FIG. 17B. As shown in FIG. 17A, (i) for the compressed data, encoder 28 carries out randomizing. Then, (ii) on the basis of the randomized data, the extended parity is generated. As explained above for Embodiment 1, for example, when the extended parity is generated, the ECC circuit 26 generates the extended parity on the basis of the data group including the randomized data and the management data.

Also, the procedure shown in FIG. 17B may be used in generating the extended parity. Here, (i) a normal parity is generated on the basis of the user data stored in the RAM 24; (ii) the user data and the normal parity are taken as a group to form a data sequence, which is compressed by the compressing part 22-2. (iii) Then, the encoder 28 carries out randomizing for the data sequence compressed in (ii). (iv) Finally, the extended parity is generated on the basis of the data sequence generated by attaching the management data to the randomized data sequence obtained in (iii).

### Effects of Embodiment 2

Due to the host equipment 1 and the memory card 2 under its control related to Embodiment 2, it is possible to obtain even better effects than the Embodiment 1. That is, it is possible to further improve error correction in read mode. As explained above, after the compression operation, the capacity of the region where the user data are stored is decreased, so that it is possible to increase the capacity of the extended parity that can be stored.

In the following, the state in which the area that can store the extended parity is increased due to the compression will be explained using specific values. For example, suppose the page size is 1024 bytes, the user size is 984 bytes, and the parity storage region is 40 bytes. Suppose the lowest data compression rate is 98%, it is possible to guarantee an idle region of about 20 bytes in the area where the user data are stored, and the parity, which has been 20 bytes, extends to 60 bytes. A simple computing indicates that error correction is improved up to about 1.5 times.

In the example of the compression system, the data sequence stored in the RAM 24 is divided into 8-bit or 4-byte parts. However, one may also adopt a scheme in which each data sequence is divided into various bit sequences, including the 8-bit data sequence and 4-byte data sequence. That is, the following scheme may also be used: the monitor part 22-1 checks the data sequence of the user data from the head and, when a designated data sequence can be formed, the portion is taken as a bit sequence, and it is then compressed. The information about how many bits should be taken for compression is stored together with the physical address of the memory cell array 11 stored in the management part 22-4 equipped in the control part 22-3 of the MPU 22.

### Modified Example 3

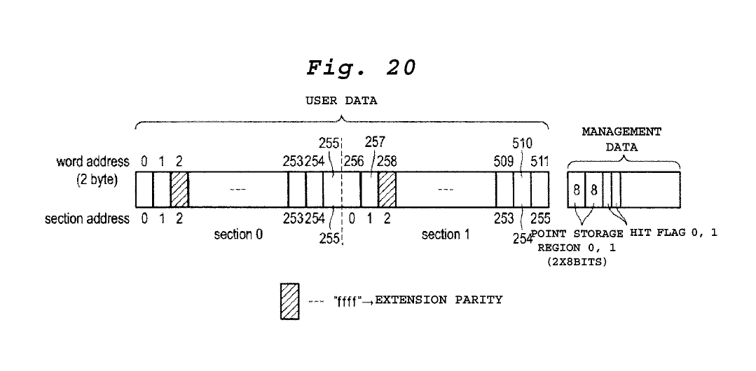

In the following, the host equipment 1 and the memory card 2 under its control of the first modified example of Embodiment 2 (hereinafter to be referred to as Modified Example 3) will be explained with reference to FIG. 18 through FIG. 20. In the embodiment, the user data are compressed, and the extended parity is stored in the idle region on each page. However, in Modified Example 3, when the storage region of the user data is compressed, the management data stored in the management data storage region are used to perform the compression operation. In the following, the compression system related to Modified Example 3 will be explained.

### (1. Constitution of MPU 22)

In the following, the constitution of the MPU 22 will be explained with reference to FIG. 18. The MPU 22 in Modified Example 3 includes a monitor part 22-1, a compressing part 22-2, a control part 22-3, a management part 22-4, and a generating part 22-5. In the following, the features identical to the examples will not be explained again.

### (1-1. Monitor Part 22-1)

In Modified Example 3, the monitor part 22-1 checks whether there is the designated data sequence in 2-byte units in the user data sent from the host equipment 1. When the monitor part 22-1 finds the designated data sequence, it checks the word address and section address (to be explained later) of the data sequence, then notifies the control part 22-3. The information notified by the monitor part 22-1 to the control part 22-3 may also be the logic address (physical address) of the data sequence. Here, as an example, an explanation will be made on the case in which the designated data sequence is “ffff” (or “1111111111111111” in binary system).

### (1-1. Control Part 22-3)

The control part 22-3 divides the data sequence of the user data in the RAM 24 into multiple groups (hereinafter to be referred to as sections). The section number may be 2 or some other number. There is no specific restriction on the dividing number. However, the dividing number is preferably that which can divide the data capacity of 1 page. In the following, the case in which the dividing number is 2 or 16 will be explained.

When the control part 22-3 is notified by the monitor part 22-1 that “ffff” is present in the data sequence, it checks what section the data corresponds to and what region in the corresponding section the data exists from the word address and section address notified by the monitor part 22-1.

Suppose dividing is carried out with a dividing number of 3 or larger, and, there is a data sequence “ffff” in 2 sections. In this case, the generating part 22-5 generates the point storage region from the control part 22-3 and from the hit flag region corresponding to the divided section number and the number of sections in which the corresponding data sequence exists among the multiple divided sections. Under these conditions, the point storage region 0 and the point storage region 1, as well as the hit flag region 0 and hit flag region 1, are generated. Here, the point storage region refers to the region arranged in the management data and having the capacity of the point storage region, and the number of point storage regions generated changes each time that write takes place. The value of the hit flag region indicates whether the address indicating the point storage region is valid. That is, when search of the data sequence “ffff” in the section is successful and the address stored in the resulting point storage region shows a valid value, “1” is stored in the hit flag region. On the other hand, when the search of the data sequence “ffff” failed, even when an address is stored in the point storage region, it still shows that this address is invalid.

In addition, the control part 22-3 writes the section address where the designated data sequence “ffff” exists in the generated point storage region. The bit number of the section address has a value corresponding to the divided section number.

In addition, the control part 22-3 stores the extended parity in the region where the data sequence “ffff” is arranged. When the write data are stored in the memory cell array 11, the data sequence is configured so that the extended parity can be stored at the tail of the page (in FIG. 6, the memory cell transistors MT corresponding to the bit lines BL(n−t) to BL(n+1)). Then, the write operation is carried out.

### (1-2. Generating Part 22-5)

When there is a command for generating the point storage region from the control part 22-3, the divided section number and the point storage region corresponding to the section number containing the designated data sequence are generated by the generating part 22-5. The same operation is carried out for the hit flag region.

### (2. Compression System)

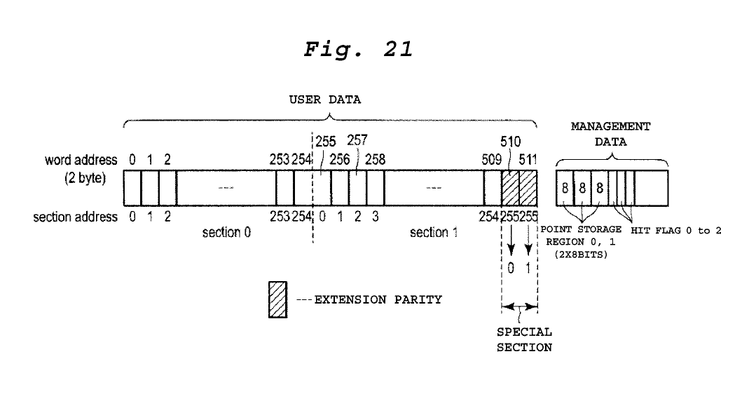

In the following, the compression system related to Modified Example 3 using FIG. 19A, FIG. 19B will be explained. FIG. 19A, FIG. 19B show the data sequence temporarily stored in the RAM 24 (user data, management data (such as 128 bytes)). Here, in order to facilitate understanding, a schematic diagram is presented to show the case in which the memory cell transistors MT are viewed in the direction of the word line WL as the data sequences are written in the memory cell array 11. That is, a schematic diagram of the page is shown. The data capacity of 1 page is 1024 bytes.

### (2-1. Dividing Number 2)

In the following, the case in which 1 page is divided into two sections, that is, section 0 and section 1 will be explained. Here, control part 22-3 sets the dividing number as explained above. As shown in FIG. 19A, when 1 page (1024 bytes) is divided into section 0 and section 1, the data capacity of each section becomes 512 bytes. Here, the data sequence in section 0 and section 1 is divided into 2-byte units, which are assigned with addresses, respectively (the word address and section address).

As the address when dividing into 2-byte units is made is taken as “word address”, as shown in FIG. 19A, the word address of section 0 is in the range of 0 to 255, and the word address of section 1 is in the range of 256 to 511. In addition, each section address of the section 0 and section 1 is in the range of 0 to 255.

Here, consider the case in which “ffff” is contained in “2” (word address) of section 0 and “258” (word address) of section 1. In this case, generating part 22-5 generates the point storage region 0 and point storage region 1, as well as hit flag region 0 and hit flag region 1. The generated point storage region 0 and point storage region 1 correspond to the position of the divided section, and they can hold the bit number that can represent the address of each section. That is, as explained above, for example, section 0 and section 1 are divided into 2-byte regions, and each region is made to correspond to 0 to 255, that is, one of a total of 256 addresses. Consequently, the bit number that can be held in the point storage region 0 is 8 bits. Similarly, the point storage region 1 also can hold bits with the bit number of 8 bits.

When the “ffff” sequence is contained in section 0 and section 1, the generating part 22-5 stores 1 in each of the hit flag 0 and hit flag 1 corresponding to these sections. When the designated data sequence is not contained in the corresponding section, 0 is stored in the hit flag.

In this way, by using the point storage region and hit flag region in the management data, it is possible to take the “ffff” data sequence contained in section 0 and section 1 as the idle region, and to carry out compression for the user data stored in each page.

### (2-2. Dividing Number 16)

In the following, with reference to FIG. 19B, the case of division of 1 page into 16 sections, that is, into section 0 to section 15, will be explained. As shown in FIG. 19B, when 1 page is divided into section 0 to section 15, the data capacity of each section is taken as 32 bytes. In addition, in these section 0 to section 15, the word address and section address of each data sequence are allotted in 2-byte units.

Just as mentioned previously, when the address allotted in 2-bytes units is taken as the word address, as shown in FIG. 19B, the word address of section 0 is taken as 0 to 31, the word address of section 1 is taken as 32 to 63, and the word address of section 15 is taken as 480 to 511. In addition, the section addresses of section 0 to section 15 are each taken as 0 to 31.

Now, suppose “ffff” is contained in “2” (word address) of section 0, “34” (word address) of section 1, . . . “450” (word address) of section 14, and “482” (word address) of section 15. In this case, generating part 22-5 generates point storage regions 0 to 15 and hit flags 0 to 15. The generated point storage region 0 to point storage region 15 correspond to the positions of the divided section 0 to section 15, and the bit number that can represent the section address of each section can be held. That is, as explained above, for example, when section 0 is divided by 2 bytes, each region corresponds to 0 to 31, that is, a total of 32 addresses. Consequently, the bit number that can be held in the point storage region 0 is 5 bits. Similarly, each of the point storage regions 1 to 15 can hold a bit number of 5 bits.

When the “ffff” sequence is contained in section 0 to section 15, the generating part 22-5 stores 1 in the hit flags corresponding to these sections.

In this way, using the point storage region in the management data, by taking the “ffff” data sequence contained in section 0 and section 1 as the idle region, compression is carried out for the user data stored in each page. Here, “ffff” is merely an example presented for explanation. The data sequence is not limited to it, as long as it can be recognized by the monitor part 22-1. For example, the data sequence of continuous “0” data and the data sequence of mixed “0” and “1” may also be used.

### (3. Write Operation)

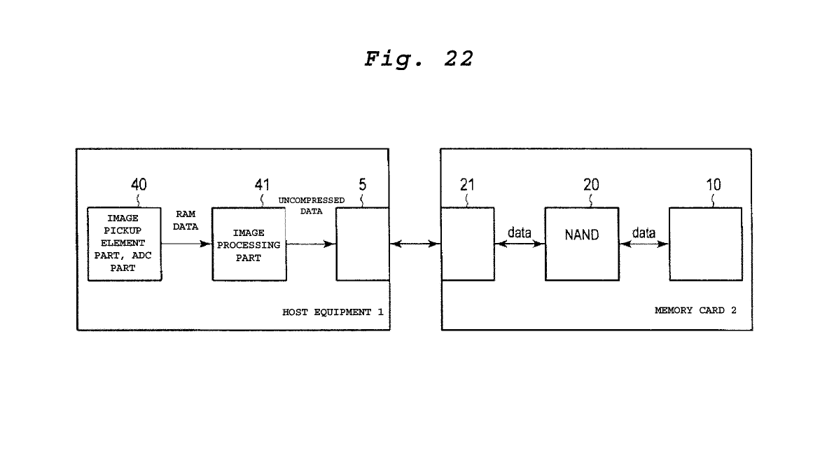

In the following, the operation ((i)-(vi)) in the memory controller 20 in the write mode will be explained with reference to FIG. 20 and FIG. 21. FIG. 20 and FIG. 21 are schematic diagrams illustrating the user data written in the RAM 24, the point storage region, and the state of storage of the hit flag. After generation of the data sequence shown in FIG. 21, the write operation is carried out. In addition, for the word address, the address is attached in 2-byte units. First of all, an explanation will be made with reference to FIG. 20. FIG. 20 is a diagram illustrating the state in which the user data sequence sent from the host equipment 1 is stored in the RAM 24.

(i) The control part 22-3 bisects the data sequence of 1024 bytes and the divided regions are taken as section 0 and section 1, respectively.

(ii) The control part 22-3 attaches, in 2-byte units, the word address and section address to each of the regions of the data sequence. Then, the monitor part 22-1 checks whether the designated data sequence is contained in each of the data sequences attached with the addresses. As a result, suppose that the “ffff” sequence is contained in word address 2 and word address 258:

(iii) Consequently, under control of the control part 22-3, the generating part 22-5 generates the point storage region 0 and point storage region 1 corresponding to the sections containing the designated data sequence. That is, the generating part 22-5 generates the following regions in the management data storage region: point storage region 0 and point storage region 1, and the hit flag 0 and hit flag 1 corresponding to the point storage regions 0, 1, respectively. The generating part 22-5 sets the regions of these point storage regions as 8 bits.

(iv) Corresponding to the value of the section address obtained by monitor part 22-1, the control part 22-3 has the bit corresponding to the section address to the point storage region. For example, if section address=2, the data sequence stored in the point storage region 0 is “00000010”. If section address=255, the data sequence is “11111111”. Consequently, although the “ffff” data sequence is not stored in the section address=2, the control part 22-3 can still recognize that the “ffff” data sequence is contained in the address of “00000010” of section 0 and the address of “00000010” of section 1. Also, the control part 22-3 stores flag 1 in the hit flags 0, 1 corresponding to the point storage regions 0, 1, respectively.

(v) As a result of the operation (iv), suppose the address of “00000010” of section 0 and section 1 is the idle region. Then, the control part 22-3 stores the extended parity in the address of “00000010” of section 0 and the address of “00000010” of section 1 that have stored the “ffff” data sequence up to that time point.

(vi) Then, when the word addresses of the extended parity shown in FIG. 20 (section 0 and section 1) are moved from “2” and “258” to the end of 1 page, the control part 22-3 first allots the word addresses 510, 511 of section 1 as section 2 (at this time, the section addresses of the section 2 are set at 0, 1) (hereinafter section 2 may be called special section), and it controls so that the generating part 22-5 generates point storage region 3 (corresponding to section 2) that holds 2 bits. Here, the bit number that can be held in the point storage region 3 is taken as “2” to ensure that the section address of section 2=0, 1 can be recognized.

Then, the extended parity is moved to the section address=0, 1 of the special section (section 3). With this operation, the data sequence before the data write operation as shown in FIG. 20 is generated.

### Effects of Modified Example 3

Even for the host equipment 1 and the memory card 2 under its control related to Modified Example 3, it is still possible to compress the user data, so that it is possible to extend the region for storing the extended parity. In Modified Example 3, the point storage region indicating the position information of the data sequence of the designated pattern is arranged in the management data storage region. That is, because it is possible to specify which section the point storage region belongs to at the position stored in the point storage region, the bit number held in the point storage region becomes smaller. Consequently, when dividing is carried out to section 0 and section 1 presented above as an example, the bit number for holding in the point storage region can be decreased from 9 bits to 8 bits. As a result, as the divided section number increases, the effect of the decrease in bit number becomes significant. As explained above, for example, in the case of dividing into 16 sections, the bit number for holding in the point storage region can be 5 bits, and it is possible to decrease the bit number for each point storage region from 9 bits to 5 bits. That is, when the data sequence of the designated pattern is present in each of the section 0 to section 15, the extendable capacity of each point storage region is 5 bits. Consequently, 16 point storage regions are generated. As a result, the increase quantity becomes 16×5 bits=90 bits and, as a result of generation of the 16 point storage regions, the increase quantity becomes 16×1 bit. That is, the increase is 90+16=116 bits.

However, the region of the data sequence (2 bytes) of the designated pattern contained in section 0 to section 15 is taken as the idle region. That is, it is possible to decrease by 16×2 byte (16 bit)=32 byte (256 bit). Consequently, it is possible to make compression for only (256−116)=140 bits. As a result, it is possible to generate the extended parity with a bit number length corresponding to the capacity of the idle region, so that it is possible to improve error correction in read mode.

### Embodiment 3

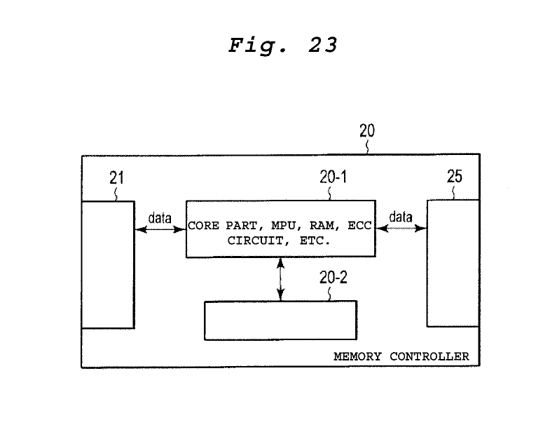

In the following, the host equipment 1 and the memory card 2 under its control related to Embodiment 3 will be explained with reference to FIG. 22 and FIG. 23. According to the present embodiment, the compression method of the video data taken by a digital camera (JPEG2000) will be explained.

### (1. Overall Configuration Example)

FIG. 22 is a diagram illustrating the host equipment 1 and the memory card 2 under its control related to Embodiment 3. The same features as those in the embodiments will not be explained again.

### (1-1. Host Equipment 1)

As shown in FIG. 22, the host equipment 1 includes an image pickup element part 40 (containing an image pickup element, an ADC part, etc.), an image processing part 41, and a host bus interface 42.

Here, the image pickup element part 40 has multiple pixel parts arranged in a matrix configuration with rows and columns. After a noise-canceling treatment for the charge (analog signal) obtained from the pixel parts with the photoelectric effect, the charge is converted to digital signal by the ADC part. The digital video data will be referred to as RAW data (uncompressed data).

The image processing part 41 carries out the following treatments for the RAW data: white balance treatment, wide dynamic range treatment, noise decreasing treatment, defective pixel correction treatment, and other video signal treatments. Then, the image processing part 41 outputs the video signal processed RAW data to the SD interface 42.

The host bus interface 42 transfers the image processed RAW data processed by the image processing part 42 to the memory card 2.

### (1-2. Memory Card 2)

Just as mentioned previously, the memory card 2 includes a NAND controller 20, an SD interface 21, and a NAND flash memory 10. In the following, the NAND controller 20 related to the present embodiment will be explained in detail with reference to FIG. 23.

### (1-2-1. Detailed Explanation of the NAND Controller 20)

In the following, the NAND controller 20 will be explained in detail with reference to FIG. 23. As shown in FIG. 23, the NAND controller 20 includes a core part 20-1, a JPEG encoder/decoder part 20-2, an SD interface 21, and a NAND interface 25. Here, according to the present embodiment, in order to simplify the explanation, the MPU 22, ROM 23, RAM 24, ECC circuit 26, register 27, and encoder 28 will be put together and referred to as core part 20-1 collectively. In addition, since the SD interface 21, NAND interface 25, and core part 20-1 are the same as mentioned previously, an explanation will be made on the JPEG encoder/decoder part 20-2 according to the present embodiment.

### (1-2-1-1. JPEG Encoder/Decoder Part 20-2)

The JPEG encoder/decoder part 20-2 compresses the video data according to the JPEG2000 code. The compression system of the JPEG2000 code is a reverse convertible compression system. With the data compression according to the JPEG2000 code, it is possible to compress the data size by about 50-60%.

### (2. Write Operation)

According to the write operation in the present embodiment, after the RAW data sent from the host equipment 1 are temporarily stored in the RAM 24, the video data are compressed according to the JPEG2000 code. Then, on the basis of the compressed data, the extended parity is generated by the ECC circuit 26. The compressed data and the extended parity are then written in the NAND flash memory 10. In the following, the operation in the NAND controller 20 in the write operation will be explained.

### (2-1. Operation in the NAND Controller 20)

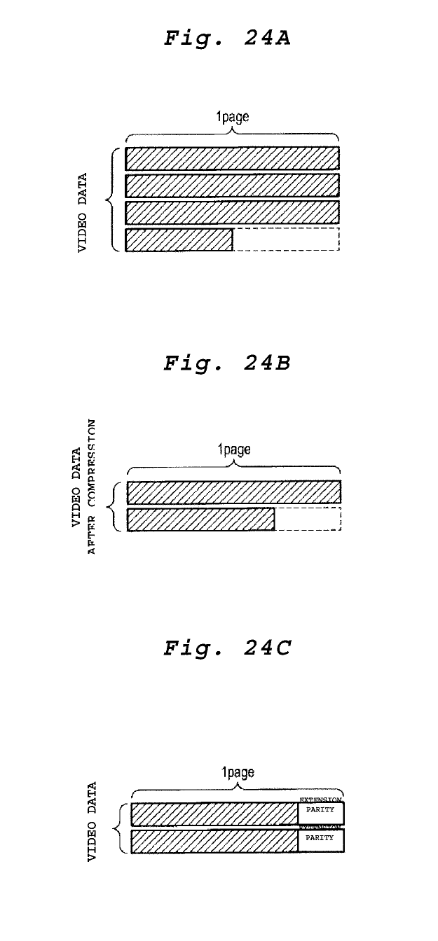

In the NAND controller 20, for the write data, the compression and generation of extended parity are carried out. In the following, explanation will be made with reference to FIG. 24A through FIG. 24C, which are schematic diagrams illustrating the case in which the compressed data and the extended parity generated by the ECC circuit 26 on the basis of the compressed data are stored in the RAM 24. In FIG. 24A through FIG. 24C, in order to facilitate understanding, the state in which the video data are stored in 1-page units is shown.

FIG. 24A is a schematic diagram illustrating the state in which, after transfer of the host equipment 1, the video data are temporarily stored in the PAM 24, and before compression is carried out for them. FIG. 24B is a schematic diagram illustrating the state in which the video data are compressed according to the JPEG2000 code. FIG. 24C is a schematic diagram illustrating the state in which the video data are divided into the various pages, and the extended parity is stored at the tail of each page.

As shown in FIG. 24A, for example, the video data, when stored, partially fill 4 pages. The JPEG encoder/decoder part 20-2 carries out compression and conversion for the video data. FIG. 24B shows the state after compression. As explained above, it is possible to make 50-60% compression for the data capacity according to the JPEG2000 code. Consequently, after compression, the video data, when stored, partially fill 2 pages. The formulas (1)-(3) are then used to compute the region for storage of the video data and extended parity that should be stored for 1 page. As a result, as shown in FIG. 24C, the evenly compressed data and the extended parity with respect to them are stored in each page. The data sequence shown in FIG. 24C is sent via the NAND interface 25 to the NAND flash memory 10.

### Effects of Embodiment 3

For the host equipment 1 and the memory card 2 under its control related to Embodiment 3, it is also possible to improve error correction in read operations. In addition, according to the present embodiment, the extended parity is generated without having the Null data continuously succeed the video data sent from the host equipment 1. However, one may also adopt a scheme in which, just as in the Embodiment 1, the extended parity is generated even when the Null data are sent from the host equipment 1.

Also, when the circuit scale of the JPEG2000 code is large and the cost is high, so that assembling of it on the memory card 2 is difficult, the function of the JPEG2000 code may also be incorporated into the host equipment 1. In this case, the host equipment 1 notifies the controller 20 that the encoded data of JPEG2000 code are written in the memory cell array 11. Upon receiving this notification, the controller 20 generates the extended parity on the basis of the encoded video data.

### Modified Example 4

In the following, the host equipment 1 and the memory card 2 under its control related to a modified example of Embodiment 3 (hereinafter to be referred to as Modified Example 4) will be explained with reference to FIG. 23. In Modified Example 4, an explanation will also be made on a digital camera as an example. Usually, for video data produced by a digital camera, in addition to the uncompressed data, there are schemes that can generate compressed data and send the data to the memory card 2. In the following, the four modes for the host equipment 1 and the memory card 2 under its control related to Modified Example 4 are listed:

Mode 1: Write of compressed data

Mode 2: Write of uncompressed data

Mode 3: Write of uncompressed data and compressed data

Mode 4: Write of uncompressed data (in the read operation, after treatment by the JPEG encoder/decoder, the data are sent to the host equipment)

### (1. Overall Constitution Example)

According to the present embodiment, the JPEG encoder/decoder part 20-2 in the various modes will be explained. As explained above, JPEG encoder/decoder part 20-2 works in any of the four modes according to the instruction from the host equipment 1.

### (Mode 1)

When there is an instruction from the host equipment 1 to work in mode 1, the JPEG encoder/decoder part 20-2 carries out encoding (compression/conversion) according to the JPEG system for the RAW data sent from the host equipment 1 via the SD interface 21 in the write operation. The compressed data encoded by the JPEG encoder/decoder part 20-2 are sent to the RAM 24, and they are then written in the NAND flash memory 10 by MPU 22.

When the encoded video data are output to the host equipment 1 in the read operation, for the video data that have been sent from the NAND flash memory 10 via NAND interface 25 and that are temporarily stored in the RAM 24, the JPEG encoder/decoder part 20-2 carries out decoding. The decoded video data are then sent via the SD interface 21 to the host equipment 1.

### (Mode 2)

When there is an instruction to work in mode 2 from the host equipment 1, the memory controller 20 writes the RAW data in the NAND flash memory 10. That is, in mode 2, the memory controller 20 carries out the write of data in the NAND flash memory 10 without performing a compression of data for the RAW data.

When the data written in the NAND flash memory 10 are read, because the stored data are uncompressed data, the memory controller 20 sends them without decoding to the host equipment 1.

### (Mode 3)

When there is an instruction to work in mode 3 from the host equipment 1, the mode 1 and mode 2 are combined. That is, the two types of data, namely, the video data encoded by the JPEG encoder/decoder part 20-2 and the uncompressed video data, are written in the NAND flash memory 10.

In the read operation, the compressed data are decoded by the JPEG encoder/decoder part 20-2 and are sent to the NAND flash memory 10, while the uncompressed data are not extended, and the data read from the NAND flash memory 10 are sent to the host equipment 1.

### (Mode 4)

In mode 4, just as in mode 2, the uncompressed data are written in the NAND flash memory 10. On the other hand, in the read operation, the uncompressed data are sent by the MPU 22 to the host equipment 1 after encoding and decoding treatment by the JPEG encoder/decoder part 20-2.

### Effects of Modified Example 4

For the host equipment 1 and the memory card 2 under its control related to Modified Example 4, the write speed to the memory card 2 can be a high speed, and it is possible to cut the memory busy-state quantity of the flash memory 10 of the memory card 2. For example, when an operation in mode 4 is carried out, in the host equipment 1, it appears to be read from the JPEG data stored in the memory card 2. Because write may be carried out only for the uncompressed data, compared with the prior art that writes both the uncompressed data and the compressed data, it is possible to shorten the write time and it is also possible to reduce the memory busy-state capacity.

Also, the circuit constitution of the JPEG encoder/decoder part 20-2 is relatively simple. Consequently, it is possible to store in the memory controller 20 at a lower cost, and the unit price of the memory card 2 will not rise significantly. For example, when the storage device is SSD (solid state drive), even when the JPEG encoder/decoder part 20-2 is assembled in the storage device, there is still no significant rise in the cost, and it is possible to assemble in a simpler way.

In the Embodiment 1, when data C are transferred from the host equipment 1, that is, even in the case in which the Null data succeeding the data are not transferred, when there is the designated idle region at the tail of the last page where the user data are written, the extended parity may be generated using the scheme used on data A and data B as explained above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of writing data in semiconductor memory cells in units of pages, comprising the steps of:
determining that data to be written into the semiconductor memory cells and received from a data source includes a designated pattern; and
writing the data in pages of the semiconductor memory cells, the pages each having a data section and a parity section that contains parity bits for error correction, wherein the parity sections of the pages are of the same size, the size being based on the designated pattern.

2. The method of claim 1, wherein the data sections of the pages are of the same size.

3. The method of claim 2, wherein the data has a length, and the size of the data section in each of the pages is equal to the length divided by the number of the pages.

4. The method of claim 3, wherein the size of the parity section in each of the pages is equal to the size of the page minus the size of the data section.

5. The method of claim 1, wherein the parity bits of a page are used to correct errors in reading data from the data section of the page.

6. The method of claim 1, further comprising:
monitoring the data to be written as the data is received from the data source for the designated pattern.

7. The method of claim 6, wherein the designated pattern corresponds to a null pattern.

8. The method of claim 1, further comprising:
determining the size of the parity section in each of the pages; and
generating the parity bits according to the determined size.

9. The method of claim 1, further comprising:
compressing the data prior to the writing,
wherein the data is written in the pages in compressed form.

10. The method of claim 9, wherein the compressed data has a length, and the size of the data section in each of the pages is equal to the length divided by the number of the pages and the size of the parity section in each of the pages is equal to the size of the page minus the size of the data section.

11. A method of writing data in semiconductor memory cells in units of pages, comprising the steps of:
determining that data to be written into the semiconductor memory cells and received from a data source includes a logic address followed by multiple consecutive groups each having a data section and a null section; and
writing the data in pages of the semiconductor memory cells, the pages each having a first section in which data from the data section of one of the groups is stored and a second section in which parity bits for error correction are stored, the size of the second section being based on the size of the data to be written into the semiconductor memory cells.

12. The method of claim 11, wherein the parity bits of a page are used to correct errors in reading data from the data section of the page.

13. The method of claim 12, wherein the data sections of the pages are of the same size, and the parity sections of the pages are of the same size.

14. The method of claim 11, further comprising:
determining the size of the parity section in each of the pages; and
generating the parity bits according to the determined size.

15. The method of claim 11, further comprising:
compressing the data prior to the writing,
wherein the data is written in the pages in compressed form.

16. A memory controller comprising:
a processor that is programmed to carry out the steps of:
determining whether a data sequence having a designated pattern over a designated data length is contained in data received from a data source;
writing the data into pages of memory cells such that an idle area of equal size is allocated for each of the pages; and
for each page, generating parity bits for error correction according to the size of the idle area and writing the parity bits into the idle area of the page.

17. The memory controller of claim 16, wherein
the processor is further programmed to compress the data prior to the writing.

18. The method of claim 16, wherein the data sequence is a pattern of repeating 1's.

19. The method of claim 18, wherein the pattern of repeating 1's appear at the end part of the data.

20. The method of claim 16, wherein the pattern of repeating 1's appear interspersed among user data.
